(19) United States
(12) Patent Application Publication
(10) Pub. No.: US 2008/0096337 A1
(43) Pub. Date: Apr. 24, 2008

(54) DISPOSABLE SEMICONDUCTOR DEVICE SPACER WITH HIGH SELECTIVITY TO OXIDE

(75) Inventor: Howard Tigelaar, Allen, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/539,203

(22) Filed: Oct. 6, 2006

(51) Int. Cl. H01L 21/8238; H01L 21/8234; H01L 29/94; H01L 21/336

(52) U.S. Cl. 438/197; 438/229; 438/230; 257/368; 257/401

(57) ABSTRACT

The invention provides, in one aspect, a method of forming a semiconductor device. The method includes forming a gate dielectric layer and a gate electrode layer over a substrate. A portion of the gate dielectric layer and gate electrode layer is etched to form a plurality of gate electrodes. A first dielectric material is formed over the substrate and the gate electrodes. A spacing layer comprising an organic material is deposited over the first dielectric material, and a portion thereof is removed to expose horizontal portions of the first dielectric material and form organic spacers on sidewalls of the gate electrodes. A first dopant is implanted through the first dielectric material into the substrate, after which the organic spacers are removed. An insulating layer is formed over the gate electrodes, and interconnects are fabricated within the insulating layer to connect the gate electrodes.

### TECHNICAL FIELD OF THE INVENTION

The invention is directed, in general, to semiconductor devices and, more specifically, to semiconductor devices fabricated using a disposable transistor sidewall spacer during dopant implantation.

### BACKGROUND OF THE INVENTION

Transistor device size continues to decrease as semiconductor device manufacturers drive to realize higher transistor density, lower power consumption, and higher speed operation of integrated circuits. As transistor device size decreases, some transistor manufacturing steps must be modified to reflect the smaller physical dimensions of the scaled transistors.

One such manufacturing step is the lightly-doped drain (LDD) implant, which is designed to reduce short channel and hot-carrier effects in MOS transistors. The dopants are typically implanted to a relatively shallow depth in the semiconductor substrate (wafer) on which the transistors are fabricated. In state-of-the-art transistor designs, a screening dielectric may be formed on the substrate surface to help reduce contamination and dopant channeling. In some cases, a portion of the implanted dopant may remain in the screening dielectric. In such cases, the dopant concentration in the substrate may depend on the thickness of the screening dielectric layer. In addition, variation in the screen dielectric layer thickness will cause variation in the depth of the dopant in the silicon.

However, the thickness of the screening oxide may vary across the substrate due to other processing steps. For example, transistor designs may employ an LDD offset spacer to block LDD implant adjacent the gate electrode. In this way, diffusion of dopant during a subsequent thermal anneal is accounted for so that the dopant is positioned correctly relative to the channel of the completed transistor. In particular, some LDD offset spacing strategies uses a thin conformal layer of silicon nitride (SiN) over the screening oxide and gate electrode. The SiN is removed on horizontal portions of the substrate, but is left remaining over the sidewall of the gate electrode. When a plasma etch is used to remove the horizontal portions, variations in the etch process across the wafer may lead to the aforementioned variation of thickness of the screening layer.

Such thickness variation may result in variation of LDD dopant concentration, junction depth, and transistor performance. Such performance variation may lead to undesirably large variation of performance of integrated circuits formed on the wafer, and decreased yield of the integrated circuits.

Accordingly, what is needed in the art is a method of manufacturing transistors to reduce the variation of screen oxide thickness and therefore transistor performance.

### SUMMARY OF THE INVENTION

The invention, in one aspect, provides a method of forming a transistor that includes forming a gate dielectric layer and a gate electrode layer over a substrate. A portion of the gate dielectric layer and gate electrode layer is etched to form a plurality of gate electrodes, and a first dielectric material is formed over the substrate and the gate electrodes. A spacing layer including an organic material is deposited over the first dielectric material, and a portion of the spacing layer is removed to expose horizontal portions of the first dielectric material and form organic spacers on sidewalls of the gate electrodes. A first dopant is implanted through the first dielectric material into the substrate, and the organic spacers are thereafter removed. An insulating layer is formed over the gate electrodes, and interconnects are fabricated within the insulating layer to connect the gate electrodes.

Another embodiment is a transistor. The transistor has a source region and a drain region located in a substrate. A channel region is located between the source region and the drain region, and a gate electrode is located over the channel region. The source and drain regions are formed using an organic sidewall spacer to protect a portion of the source and drain regions from implantation with a dopant.

Another embodiment is a semiconductor device. The semiconductor device has transistors manufactured using a method that includes forming a gate dielectric layer and a gate electrode layer over a substrate. A portion of the gate dielectric layer and gate electrode layer is etched to form a plurality of gate electrodes. A layer having a first dielectric material is formed over the substrate and the gate electrodes. A spacing layer including an organic material is deposited over the first dielectric material. A portion of the spacing layer is removed to expose horizontal portions of the first dielectric material and form spacers on sidewalls of the gate electrodes. A first dopant is implanted through the first dielectric material into the substrate. The spacers are removed subsequent to implanting the dopant. The semiconductor device includes a plurality of dielectric layers with vias and interconnects therein connecting the transistors.

Another embodiment is a semiconductor device having a plurality of transistors. The transistors include a source region and a drain region located in a substrate. A channel region is located between the source region and drain region. A gate electrode having a gate length of about 45 nm or less is located over the channel region. The transistors include an offset spacer adjacent the gate electrode, where the offset spacer consists essentially of one or more L-shaped portions of silicon dioxide. The transistors are connected by a plurality of dielectric layers with vias and interconnects formed therein.

### BRIEF DESCRIPTION OF THE DRAWINGS

For a more complete understanding of the present invention, reference is now made to the following descriptions taken in conjunction with the accompanying drawings, in which:

FIGS. 1A-1D, 2A-2D and 3 are sectional views illustrating a semiconductor device at various stages of an example process sequence according to the principles of the invention;

FIGS. 4A-4C are sectional views illustrating an alternate embodiment of forming a semiconductor device according to the principles of the invention; and

FIG. 5 is a sectional view illustrating an integrated circuit formed according to the principles of the invention.

### DETAILED DESCRIPTION

In the following detailed description and Figures, those skilled in the semiconductor arts will appreciate that layer thicknesses are not drawn to scale and may vary among manufacturers and among different process sequences used by a single manufacturer. Furthermore, later Figures may make continuing reference to reference numerals of features described in previous drawings that have not been substantially altered in the later Figure.

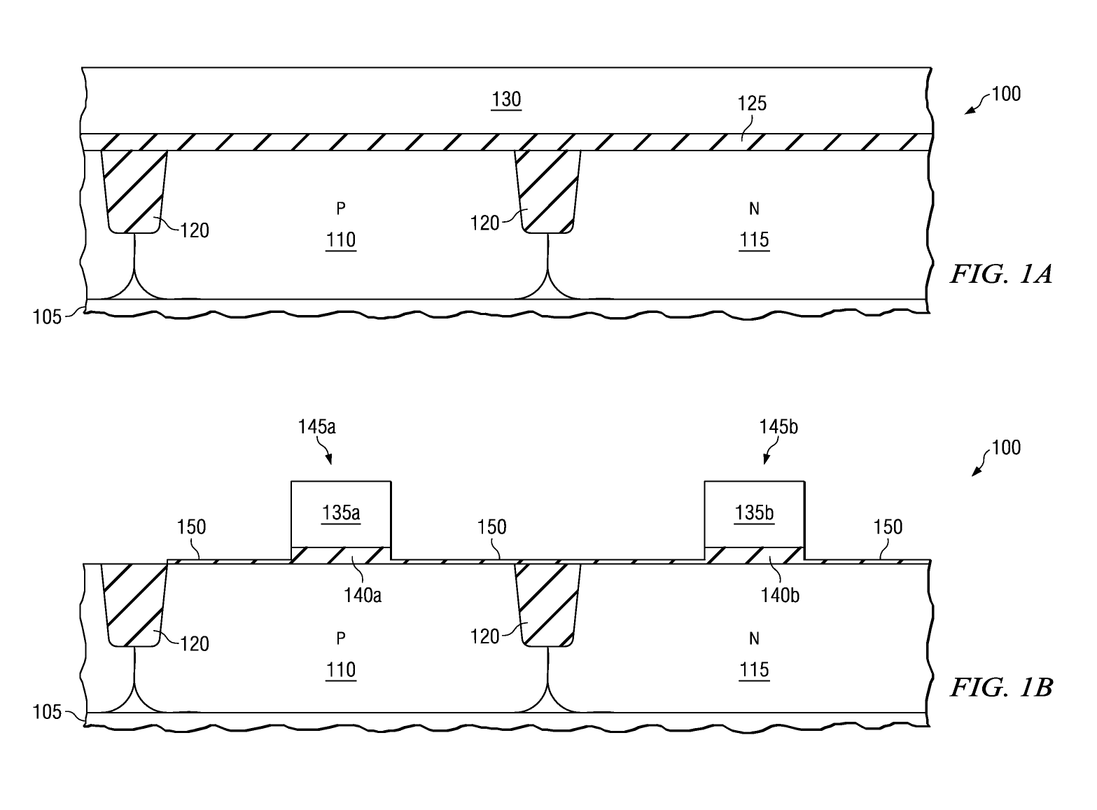

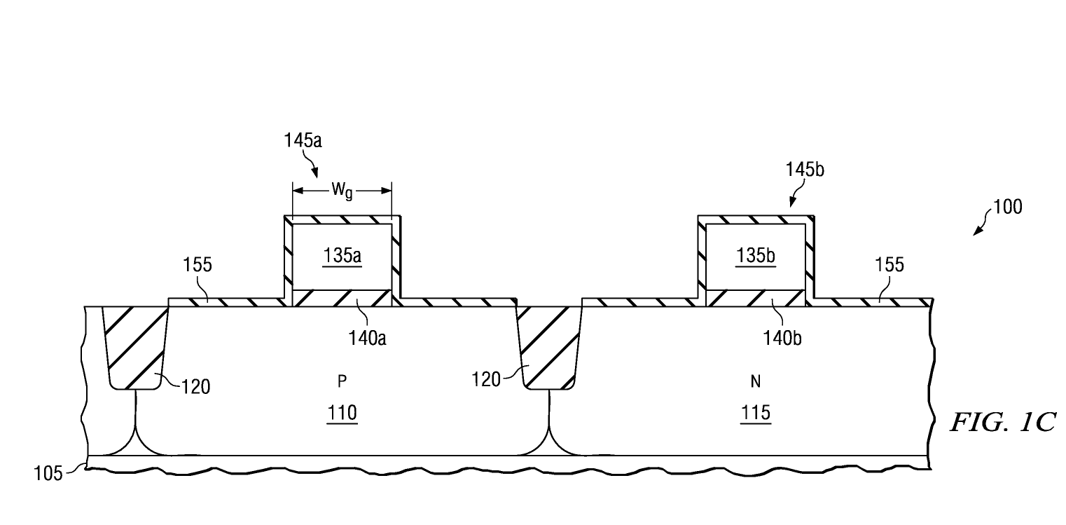

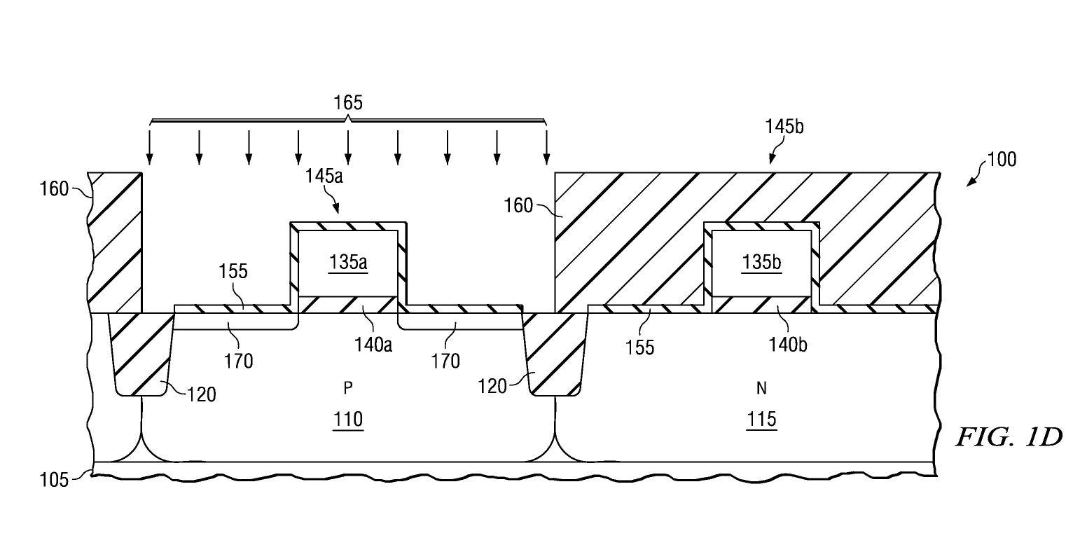

FIG. 1A illustrates a semiconductor device 100 on a substrate 105. The substrate 105 may be a semiconductor wafer, and in some cases may be silicon. Semiconductor substrates other than silicon, e.g., GaAs, are contemplated and are within the scope of the invention. The substrate 105 may also be an epitaxial layer formed on a wafer, or may be a silicon-on-insulator (SOI) wafer. Without limitation, embodiments presented in the following discussion assume that the substrate 105 is a silicon wafer.

The substrate 105 has been processed to produce a p-well 110 and an n-well 115, over which an n-MOS transistor and p-MOS transistor are respectively to be formed. A trench isolation structure 120 has been formed between the p-well 110 and n-well 115. A gate dielectric layer 125 and a gate electrode layer 130 have been formed over the substrate 105. The gate dielectric layer 125 may be any currently existing or future gate dielectric material, e.g., silicon oxide, silicon nitride, silicon oxynitride (denoted herein SiO, SiN and SiON, respectively), or a high-k gate dielectric. Examples of the gate electrode layer 130 include semiconducting materials such as polysilicon or a metal such as TiN, TaC, or W.

FIG. 1B illustrates the semiconductor device 100 after selective removal of portions of the gate electrode layer 130 and the gate dielectric layer 125. The removal has formed a gate electrode 135a and gate insulator 140a of an n-MOS transistor 145a, and a gate electrode 135b and gate insulator 140b of a p-MOS transistor 145b. The gate electrodes 135a, 135b and gate insulators 140a, 140b may be formed conventionally by, e.g., patterning of a resist layer and plasma etching. A remaining portion 150 of the gate dielectric layer may remain after definition of the gate insulators 140a, 140b. This remaining portion 150, if present, may be very thin, e.g., usually less than about 1 nm.

FIG. 1C illustrates the semiconductor device 100 after formation of a screen oxide layer 155. The screen oxide layer 155 may be formed by thermal oxidation of the substrate 105 and gate electrodes 135a, 135b when polysilicon is used as the gate material, or deposited when metallic gate electrodes are used. The screen oxide layer 155 is also formed over exposed surfaces of the gate electrodes 135a, 135b. Because the remaining portion 150 of the gate dielectric layer is generally thin, it is usually subsumed by the screen oxide layer 155.

In some cases, a first implant is performed after the screen oxide layer 155 is formed. This implant step is commonly referred to as a lightly-doped drain, or LDD implant. The LDD implant is typically shallow enough that a portion of the implanted dopant remains in the screen oxide layer 155. This aspect is enhanced in devices with a gate length W_{g} of about 45 nm or less, as the implant depth may roughly scale with the gate length. That is, as gate lengths continue to shrink to or below 45 nm, more of the LDD implant remains in the screen oxide layer 155. As such, it is beneficial that the thickness of the screen oxide layer 155 be as uniform as possible. The thickness of the screen oxide layer 155 may be controlled to assist positioning the peak concentration of the implanted dopant at a desired depth below the surface of the p-well 110 and the n-well 115.

In FIG. 1D, a resist layer 160 has been formed and patterned to expose the n-MOS transistor 145a. A first LDD implant 165 is performed to form n-LDD regions 170 in the p-well 110. Typical n-type dopants such as phosphorous (P) or arsenic (As) may be used as the dopant. A HALO (high angle, low-energy) implant, using a dopant such as boron (B), may optionally be performed at this time to help control short channel effects. After implantation of the n-type dopant, the n-MOS transistor 145a may optionally be annealed to reduce damage to the semiconductor lattice from the implantation to reduce enhanced diffusion of the dopant during subsequent thermal steps.

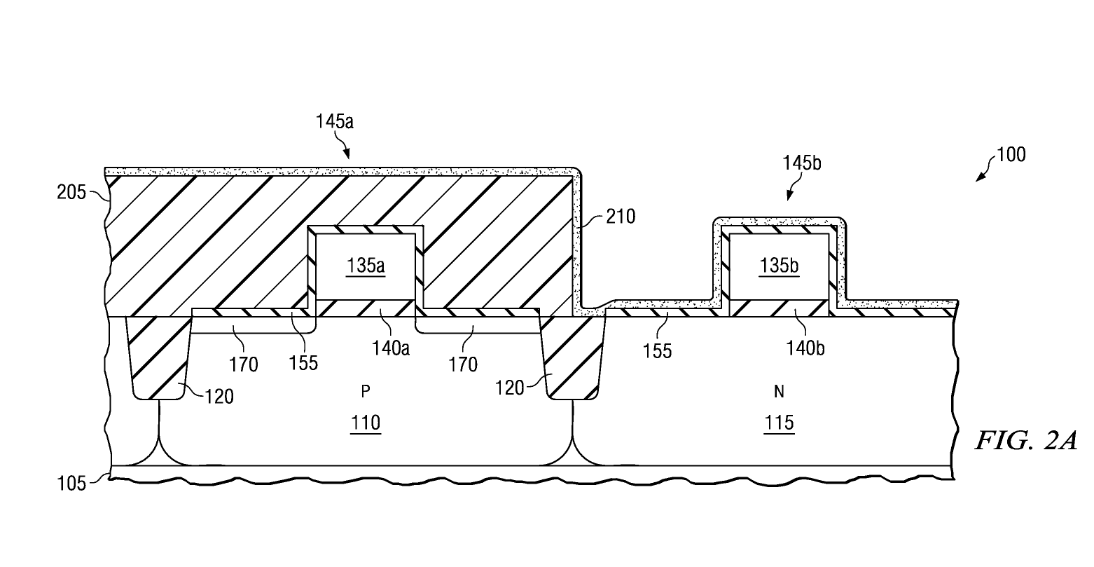

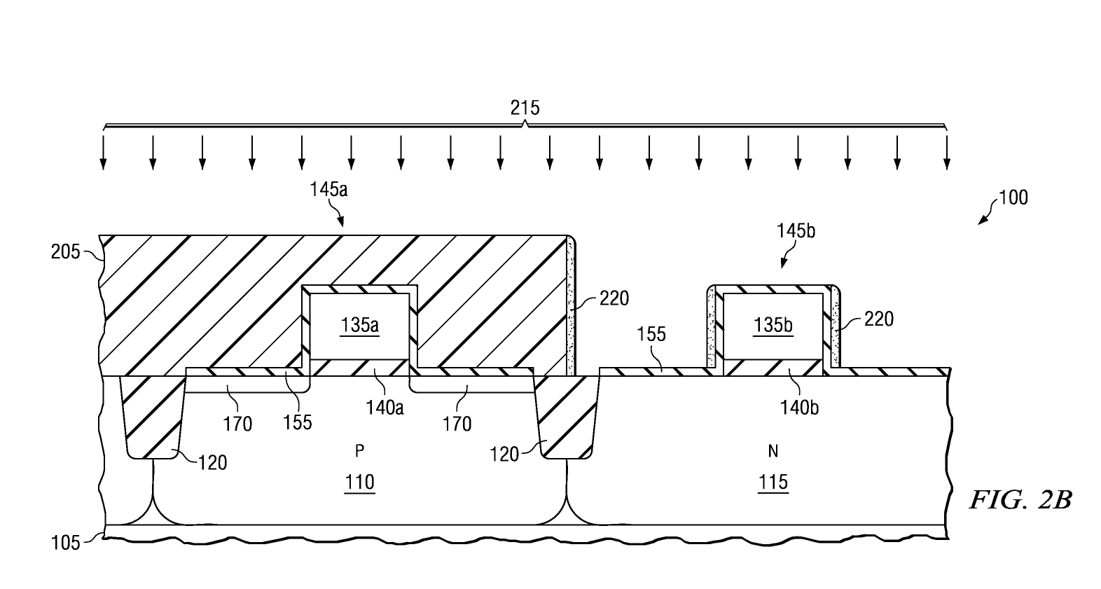

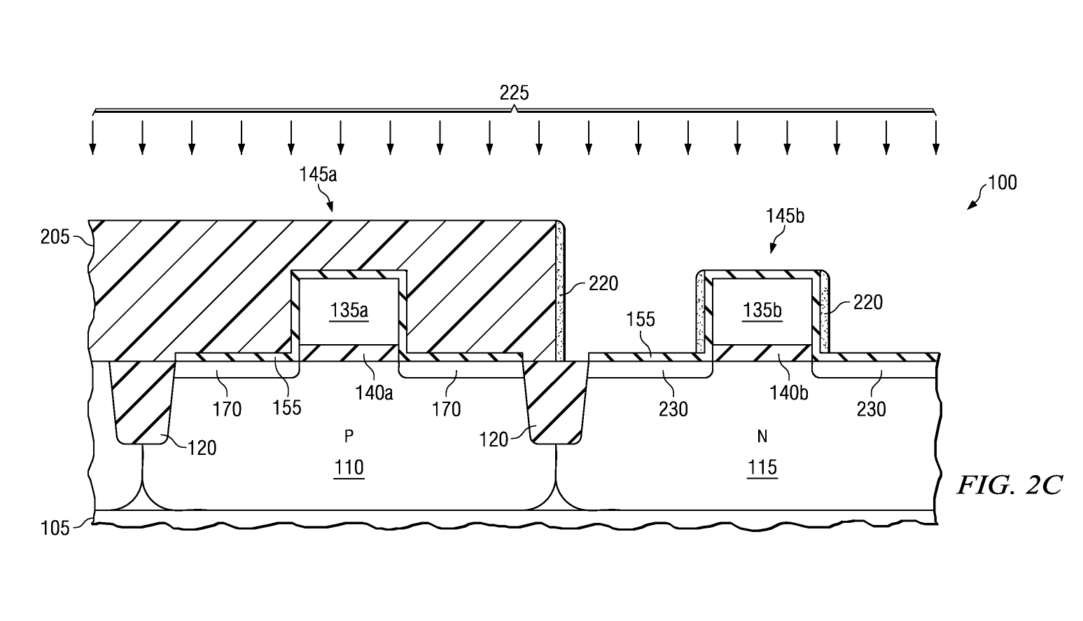

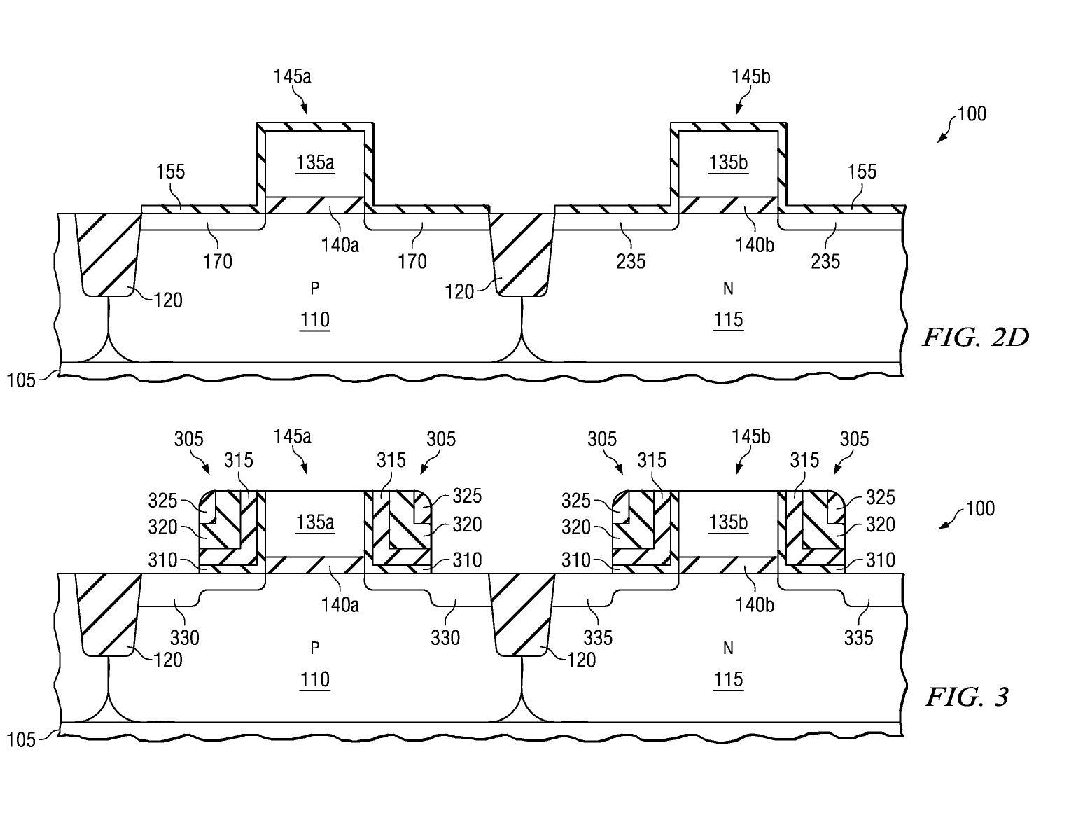

FIG. 2A illustrates the semiconductor device 100 after removing the resist layer 160 by conventional means and forming and patterning a resist layer 205. As discussed below, an organic layer 210 is also formed over the resist layer 205 and the substrate 105. The resist layer 205 has been patterned to expose the p-MOS transistor 145b. A second LDD implant will be performed using a p-type dopant to form p-LDD regions in the n-well 115. Boron, which may be implanted in the form of BF₂, is typically used as the p-type dopant.

Because boron diffuses relatively rapidly through silicon, certain issues arise. When a post-implant anneal is performed after boron doping, the boron may diffuse laterally under the gate insulator 140b. Such diffusion is typically compensated for by forming a dielectric spacer over the sidewall of the gate electrode 135b to horizontally displace the implanted boron away from a channel region underlying the gate electrode 135b. Thus, when the post-implant anneal causes the boron to diffuse laterally, the boron is positioned properly at the end of the diffusion process.

Conventional spacers are typically formed by depositing a SiN layer over the screen oxide layer 155 with a plasma process. However, because the etch selectivity of SiN to SiO is typically low, the thickness of the screen oxide layer 155 varies across the substrate 105. This thickness variation may result in a difference of the peak concentration of the p-type dopant implanted in the n-well 115 in those areas where the screen oxide layer 155 is particularly thin, which in turn, may result in undesirable variability of the electrical characteristics of transistors across the substrate 105.

The variation that occurs in conventional processes can be reduced by using the organic layer 210 as a sidewall spacer material. Because an organic material may be removed with high selectivity to the underlying screen oxide layer 155, the thickness variation of the screen oxide layer 155 is reduced, and improved uniformity of transistor properties results.

The organic layer 210 may be formed in a conformal manner, so that the thickness of the organic layer 210 is about the same over a sidewall of the gate electrode 135b as over horizontal surfaces of the substrate 105. The thickness may be chosen to result in a desired offset of subsequently implanted dopants from the sidewall of the gate electrode 135b. In some cases, this thickness will be about 100 nm. Organic materials that may be deposited conformally include chemical vapor deposited (CVD) polymers or plasma deposited polymers. As defined herein, “polymer” includes materials that are macromolecules with repeating chemical units, or a solid, organic material composed of chemically bonded molecular fragments. The polymer may further be linear or cross-linked.

Those skilled in the art understand that a CVD polymer may be formed in a highly conformal manner by the chemical combination of monomer units on a surface. One class of such polymers is known as parylenes. Parylenes may be formed by producing a concentration of monomer units in a gas phase. The monomer may react to form a polymer film on surfaces of a substrate placed in the presence of the gas-phase monomers. The details of producing parylenes are well known to those skilled in the pertinent art. Polymer-like material may also be formed under certain conditions in a fluorocarbon-based plasma. Such plasmas are widely used in semiconductor manufacturing. Such polymer-like material may be formed in a manner that results in a substantially conformal coating on the semiconductor substrate. These examples of conformal organic coatings are not exhaustive. Other currently known and later discovered methods of forming organic conformal coatings are contemplated and are within the scope of the invention.

In FIG. 2B, a plasma process 215 may be used to remove those portions of the organic layer 210 on the horizontal surface of the substrate 105, while leaving a vertical portion 220 of the organic layer 210 over the sidewall of the gate electrode 135b. The plasma process 215 is designed to have a high selectivity to the screen oxide layer 155. Use of a high selectivity process results in a negligible amount of the screen oxide layer 155 being removed by the plasma process 215. Thus, the thickness of the exposed screen oxide layer 155 substantially retains the uniformity with which it was formed.

An example of a process having the desired selectivity is an anisotropic oxygen-containing etch. Specific parameters are typically dependent on the process tool used. Generally, however, an anisotropic oxygen-containing etch may be an O₂/CO or O₂/CO₂ plasma operated at low pressure (about 20 mT or less) and with a high bias power. A plasma process 215 having these characteristics is expected to have a selectivity to an underlying oxide layer, e.g., greater than about 10:1. One skilled in the art would have the knowledge and skill required to determine suitable process parameters specific to the process tool used.

FIG. 2C illustrates an implant process 225 used to deposit a p-type dopant into the surface of the substrate to create a p-LDD region 230. The vertical portion 220 of the organic layer 210 over the sidewall of gate electrode 135b blocks implant of the dopant in that portion of the n-well 115 adjacent the gate electrode 135b and offsets the p-LDD region 230 from the gate electrode 135b. At this time a HALO implant, typically including arsenic or phosphorus, may optionally be performed to control short channel effects. Subsequent to the p-LDD implant, the resist layer 205 and vertical portion 220 are removed by a cleanup process (not shown) which may be, e.g., an isotropic oxygen ash.

In FIG. 2D, a post-implant anneal has been performed, resulting in lateral diffusion of the p-type dopant deposited by implant process 225 to produce a desired dopant profile 235. As noted previously, the high selectively of the plasma process 215 to the screen oxide layer 155 results in substantial retention of the initial uniformity of the screen oxide layer 155. This aspect allows for a more uniform dopant concentration in the p-LDD regions 235 across the substrate and within a device, improving uniformity of transistor electrical characteristics.

FIG. 3 illustrates an embodiment of the semiconductor device 100 having conventional offset spacers 305 horizontally displace source/drain implants (not shown) away from the gate electrodes 135a, 135b. The offset spacer 305 comprises a first oxide portion 310, which may be a remaining portion of the screen oxide layer 155. A second oxide portion 315 is formed over the first oxide portion 310. A SiN portion 320 is in contact with the second oxide portion 315, and a third oxide portion 325 is formed over the SiN portion 320.

If a conventional process sequence had been used to form the offset spacer to position the p-LDD dopant, a remaining portion of SiN would typically be present between the first oxide portion 310 and the second oxide portion 315. The absence of this SiN portion provides an additional advantage by reducing the amount of material with relatively high dielectric constant from close proximity to the gate electrode 135b. For example, without limitation, plasma deposited SiN has a dielectric constant of about 8, while the dielectric constant of plasma deposited SiO is about 4. By reducing the amount of material with a relatively high dielectric constant from the immediate proximity to the gate electrode 135b, capacitive coupling of the gate electrode 135b to surrounding device features and the substrate may be reduced. This reduction may result in an increase in device speed and reduction in power dissipation.

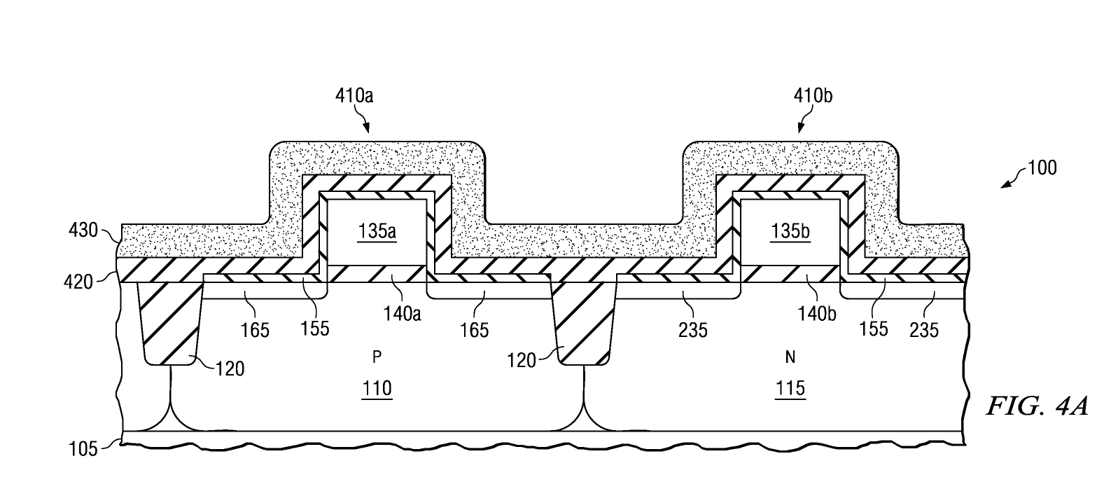

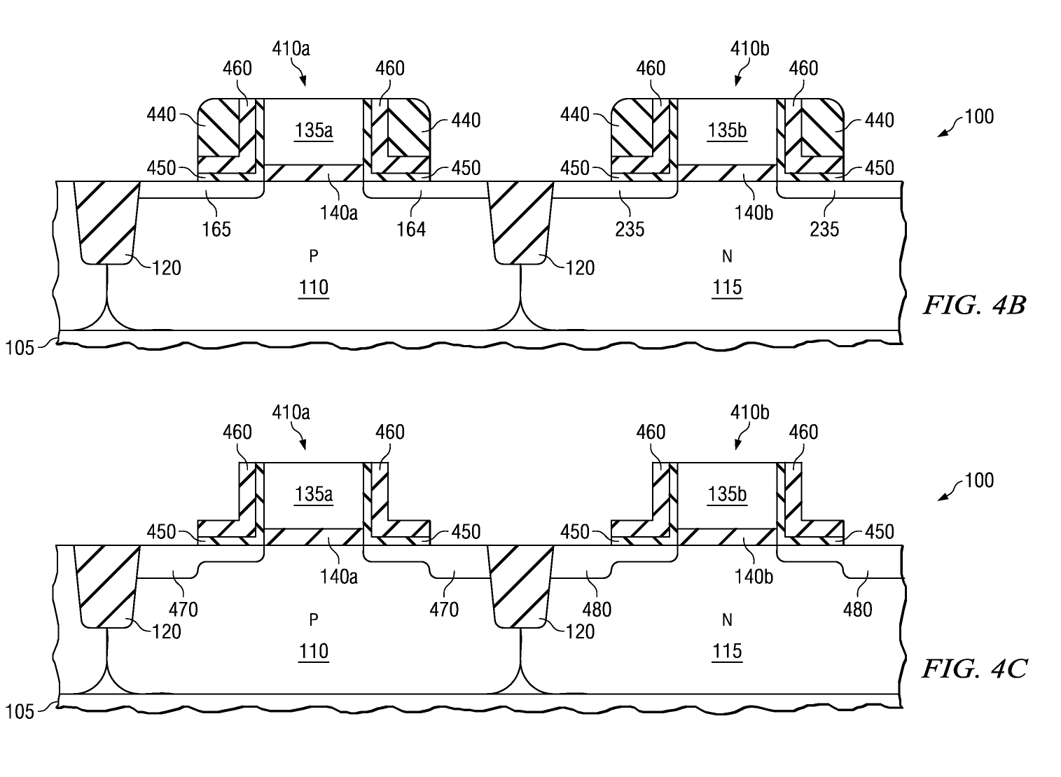

FIGS. 4A-4C illustrate an alternative embodiment of a method of forming the transistors 410a, 410b using an organic spacer to block source/drain dopants. In FIG. 4A, a dielectric layer 420 such as SiO has been formed over the screen oxide 155. An organic layer 430, as previously described, has been formed over the dielectric layer 420. The organic layer 430 will typically be thicker than the organic layer 210. For example, a typical offset distance for source/drain implant spacers is on the order of about 1000 nm, whereas the offset of the LDD implant is typically on the order of about 100 nm.

In FIG. 4B, etch processing has been used to remove a portion of the organic layer 430 to form an organic portion 440. Portions of the screen oxide layer 155 and the dielectric layer 420 have been removed to respectively form a first oxide portion 450 and a second oxide portion 460. The portions 440, 450 and 460 may be formed using a combination of anisotropic oxygen ash and anisotropic oxide etch processes. Specific process parameters are dependent on the specific etch tool set and layer thicknesses, and may be determined by one skilled in the plasma etch arts without undue experimentation.

In FIG. 4C, the organic portions 440 have been removed by, e.g., an oxygen ash process, and source/drain implants and thermal anneal (not shown) have been performed to produce the desired source/drain dopant profiles 470, 480. The first and second oxide portions 450 and 460 remain. Comparing FIG. 4C with FIG. 3, it is apparent that a process using the organic material to form the source/drain spacers results in the elimination of the SiN layer 320. This elimination may result in additional improvement of the performance of the semiconductor device 100 by reducing capacitive loading on the gate electrode 135b.

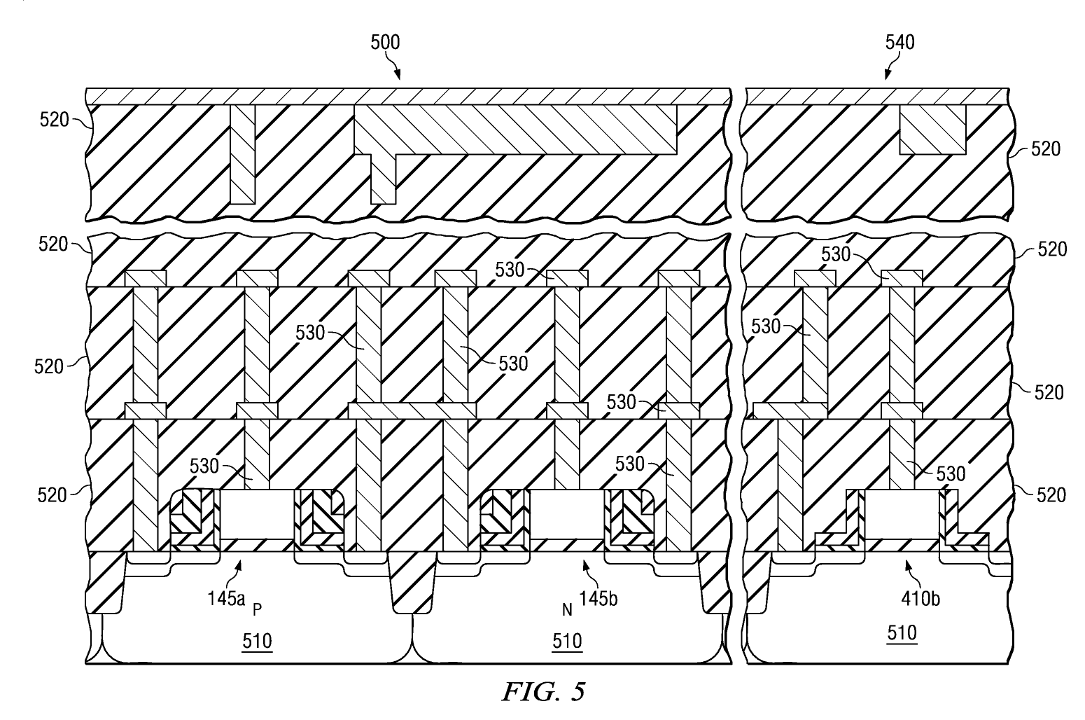

Turning to FIG. 5, illustrates an integrated circuit (IC) 500 incorporating transistors 145a, 145b. The transistors 145a, 145b are formed over a substrate 510 by the method of using an organic offset spacer as described herein. The IC 500 may include MOS, BiCMOS or bipolar components, and may further include passive components, such as capacitors, inductors or resistors. It may also include optical components or optoelectronic components. Those skilled in the art are familiar with these various types of components and their manufacture. The IC 500 may also be a dual-voltage IC, comprising transistors operating with difference threshold voltages.

Dielectric layers 520 may be fabricated over the transistors 145a, 145b using currently known or later discovered methods. Additionally, interconnect structures 530 are located within the dielectric layers 520 to connect various components, thus forming the operational integrated circuit 500. It will be apparent to one skilled in the art that several variations of the example interconnect architecture may be fabricated according to the principles of the invention with similarly advantageous results.

IC 540 illustrates an alternate embodiment incorporating a transistor 410b formed using an organic source/drain implant spacers as described herein. The method of using an organic offset spacer as described herein may also be used to form the transistor 410b.

Those skilled in the art to which the invention relates will appreciate that other and further additions, deletions, substitutions and modifications may be made to the described embodiments without departing from the scope of the invention.

1. A method of forming a semiconductor device, comprising:
forming a gate dielectric layer and a gate electrode layer over a substrate;
etching a portion of said gate dielectric layer and gate electrode layer to form a plurality of gate electrodes;
forming a first dielectric material over said substrate and said gate electrodes;
forming a screen oxide layer over said dielectric material and said gate electrodes;
depositing a spacing layer comprising an organic material over said screen oxide layer;
removing a portion of said spacing layer to form organic spacers on sidewalls of said gate electrodes;
implanting a first dopant through said screen oxide layer into said substrate;
removing said organic spacers subsequent to said implanting;
forming an insulating layer over said gate electrodes; and
fabricating interconnects within said insulating layer to connect said gate electrodes.

2. The method as recited in claim 1, wherein said organic material is parylene, a derivative of parylene, or a plasma deposited polymer.

3. The method as recited in claim 1, further comprising implanting a second dopant into said substrate, wherein second spacers are formed adjacent said sidewalls prior to implanting said second dopant.

4. The method as recited in claim 3, wherein said second spacers comprise parylene, a derivative of parylene, or a plasma-deposited polymer.

5. The method as recited in claim 1, wherein said etching exposes said substrate.

6. The method as recited in claim 5, wherein forming said screen oxide layer comprises oxidizing said first dielectric material.

7. The method as recited in claim 1, wherein removing said organic spacers removes substantially none of said screen oxide layer.

8. The method as recited in claim 1, wherein said portion of said spacing layer is removed using a plasma etch process.

9. (canceled)

10. A semiconductor device comprising:
transistors manufactured using a method comprising:
forming a gate dielectric layer and a gate electrode layer over a substrate; etching a portion of said gate dielectric layer and gate electrode layer to form a plurality of gate electrodes;
forming a screen oxide layer over said substrate and said gate electrodes;
depositing a spacing layer comprising an organic material over said screen oxide layer;
removing a portion of said spacing layer to expose horizontal portions of said screen oxide layer and form spacers on sidewalls of said gate electrodes;
implanting a first dopant through said screen oxide layer into said substrate; and
removing said spacers subsequent to said implanting; and
a plurality of dielectric layers with vias and interconnects formed therein connecting said transistors.

11. The semiconductor device as recited in claim 10, wherein said organic material is parylene, a derivative of parylene, or a plasma-deposited polymer.

12. The semiconductor device as recited in claim 10, wherein a width of at least one of said gate electrodes is about 45 nm or less.

13. The semiconductor device as recited in claim 10, wherein a second spacer is formed on said sidewalls prior to implanting a second dopant into said substrate, wherein said second spacer comprises a second dielectric material.

14. The semiconductor device as recited in claim 13, wherein said second spacers comprise silicon nitride.

15. The semiconductor device as recited in claim 10, wherein said etching exposes said substrate.

16. The semiconductor device as recited in claim 15, wherein a layer comprising said screen oxide layer is formed over said exposed substrate prior to implanting said first dopant.

11. The semiconductor device as recited in claim 10, wherein removing said spacers removes substantially none of said screen oxide layer.

18. The semiconductor device as recited in claim 10, wherein said first dielectric comprises silicon dioxide.

19. The semiconductor device as recited in claim 10, further comprising a plurality of dielectric layers with vias and interconnects formed therein connecting said transistors.

20. (canceled)

21. The method as recited in claim 6, wherein said oxidizing comprises thermal oxidation.
